(19) United States
(12) Patent Application Publication
(10) Pub. No.: US 2024/0088335 A1
(43) Pub. Date: Mar. 14, 2024

(54) LIGHT-EMITTING DEVICE AND LIGHT-EMITTING ELEMENT

(71) Applicant: Quanzhou sanan semiconductor technology Co., Ltd., Fujian (CN)

(72) Inventors: Xiushan ZHU, Fujian (CN); Ji CHEN, Fujian (CN); Yan LI, Fujian (CN); Qi JING, Fujian (CN); Chungying CHANG, Fujian (CN); Chiming TSAI, Fujian (CN); Zhilong LU, Fujian (CN)

(73) Assignee: Quanzhou sanan semiconductor technology Co., Ltd., Fujian (CN)

(21) Appl. No.: 18/448,953

(22) Filed: Aug. 13, 2023

(30) Foreign Application Priority Data
Sep. 13, 2022 (CN) 202211108404.3

(51) Int. Cl. H01L 33/60; H01L 33/50; H01L 33/62

(52) U.S. Cl. CPC H01L 33/60; H01L 33/50; H01L 33/62

(57) ABSTRACT

Disclosed is a light-emitting device which includes a light-emitting element and a wavelength conversion layer, and light of a first wavelength emitted by the light-emitting element is converted into light of a second wavelength and light of a third wavelength through the wavelength conversion layer. The light-emitting element includes a first contact layer, and the reflectivity of the first contact layer to the third wavelength is greater than 85%, so that the reflectivity of the light of the second wavelength and the light of the third wavelength converted by the wavelength conversion layer and reflected to the surface of the light-emitting element may be increased, and the white light conversion efficiency and the light extraction efficiency of the light-emitting device are improved.

### CROSS-REFERENCE TO RELATED APPLICATION

This application claims the priority benefit of China application serial no. 202211108404.3, filed on Sep. 13, 2022. The entirety of the above-mentioned patent application is hereby incorporated by reference herein and made a part of this specification.

### BACKGROUND

### Technical Field

The present disclosure relates to a light-emitting device, and in particular to a light-emitting device having a light-emitting element.

### Description of Related Art

Light-emitting diode (LED) is a solid-state semiconductor light-emitting element, and has the advantages of low power consumption, low heat energy, long service life, being shockproof, small volume, fast response speed and good photoelectric characteristic, such as stable emission wavelength. Therefore, light-emitting diodes are commonly adopted in household appliances, equipment indicator lights, and photoelectric products.

Some existing light-emitting elements use a reflective metal layer as the main reflector material to achieve better reflection of light emitted by the light-emitting element. However, the reflective metal layer is not entirely covered on the surface of the light-emitting element, and the surface of the light-emitting element in contact with the N ohmic contact electrode is not covered by the reflective metal layer, so the reflectivity of the N ohmic contact electrode material will also affect the brightness of light-emitting element.

Chinese patent document CN202110839925.5 discloses a light-emitting diode, which includes: a first semiconductor layer, an active layer, a second semiconductor layer, a second metal reflective layer formed on the second semiconductor layer, and a first metal reflective layer forming an ohmic contact with the first semiconductor layer. The first metal reflective layer uses Al to directly contact the first semiconductor layer, so as to increase the reflectivity of the N ohmic contact electrode, thereby improving the brightness of the light-emitting element.

### SUMMARY

In an embodiment of the present disclosure, a light-emitting device is provided, which includes: a light-emitting element, which emits light of a first wavelength; and a wavelength conversion layer, which covers the light-emitting element, the wavelength conversion layer includes a first wavelength conversion material and a second wavelength conversion material, light of the first wavelength emitted by the light-emitting element is converted into light of a second wavelength through the first wavelength conversion material, and light of the first wavelength emitted by the light-emitting element is converted into light of a third wavelength through the second wavelength conversion material. The light-emitting element includes: a semiconductor stack layer, which includes a first semiconductor layer, a second semiconductor layer, and an active layer between the first semiconductor layer and the second semiconductor layer; and a contact layer, which includes a portion in contact with the first semiconductor layer; the reflectivity of the contact layer to the third wavelength is greater than 85%, the reflectivity of the contact layer to the third wavelength is greater than the reflectivity of the contact layer to the first wavelength, and the reflectivity of the contact layer to the second wavelength is greater than the reflectivity of the contact layer to the first wavelength.

As described above, the disclosure provides a light-emitting device which includes a light-emitting element and a wavelength conversion layer. Light of the first wavelength emitted by the light-emitting element is converted into light of the second wavelength and light of the third wavelength through the wavelength conversion layer. The light-emitting element includes a first contact layer, and the reflectivity of the first contact layer to the third wavelength is greater than 85%, so that the reflectivity of the light of the second wavelength and the light of the third wavelength converted by the wavelength conversion layer and reflected to the surface of the light-emitting element may be increased, and thereby the white light conversion efficiency and the light extraction efficiency of the light-emitting device may be improved.

### BRIEF DESCRIPTION OF THE DRAWINGS

FIG. 1 is a cross-sectional view of a light-emitting device 1 disclosed by an embodiment of the present disclosure.

FIG. 2 is a cross-sectional view of a light-emitting element 2 formed with a semiconductor stack layer in an embodiment of the present disclosure.

FIG. 3, FIG. 4 and FIG. 5 are a top view, a partial enlarged view and a cross-sectional view of the light-emitting element 2 formed with a semiconductor structure in an embodiment of the present disclosure.

FIG. 6, FIG. 7 and FIG. 8 are a top view, a partial enlarged view and a cross-sectional view of the light-emitting element 2 formed with a transparent conductive layer in an embodiment of the present disclosure.

FIG. 9, FIG. 10 and FIG. 11 are a top view, a partial enlarged view and a cross-sectional view of the light-emitting element 2 formed with a first insulating layer in an embodiment of the present disclosure.

FIG. 12, FIG. 13 and FIG. 14 are a top view, a partial enlarged view and a cross-sectional view of the light-emitting element 2 formed with a metal layer in an embodiment of the present disclosure.

FIG. 15, FIG. 16 and FIG. 17 are a top view, a partial enlarged view and a cross-sectional view of the light-emitting element 2 formed with a second insulating layer in an embodiment of the present disclosure.

FIG. 18, FIG. 19 and FIG. 20 are a top view, a partial enlarged view and a cross-sectional view of the light-emitting element 2 formed with a contact layer in an embodiment of the present disclosure.

FIG. 21, FIG. 22 and FIG. 23 are a top view, a partial enlarged view and a cross-sectional view of the light-emitting element 2 formed with a third insulating layer in an embodiment of the present disclosure.

FIG. 24 and FIG. 25 are a top view and a cross-sectional view of the light-emitting element 2 formed with a contact layer in an embodiment of the present disclosure.

FIG. 26 is a reflectivity diagram of Al and Cr/Ag to 400 nm to 700 nm band.

FIG. 27 is a reflectivity diagram of Cr in Cr/Ag of different thickness to 400 nm to 700 nm band.

FIG. 28 is a cross-sectional view of a light-emitting element 3 disclosed in an embodiment of the present disclosure.

### DESCRIPTION OF THE EMBODIMENTS

To make the purpose of the embodiment of the present disclosure, technical scheme and advantage clearer, the technical scheme in the embodiment of the present disclosure is clearly and completely described below in conjunction with accompanying drawing in the embodiment of the present disclosure. Clearly, the embodiments are some of the embodiments of the present disclosure, but not all of them.

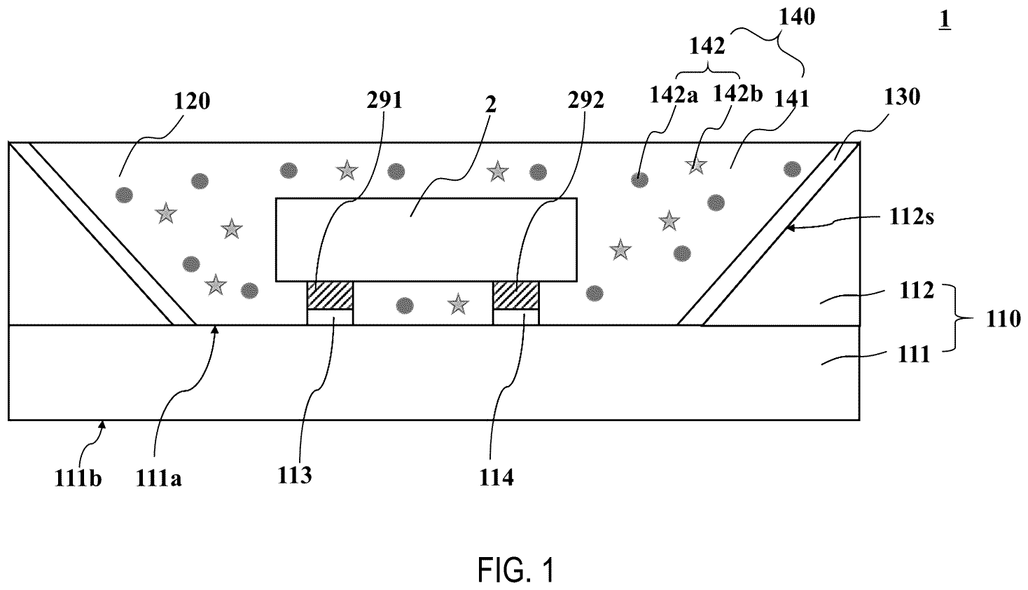

FIG. 1 is a schematic diagram of a light-emitting device 1 according to an embodiment of the present disclosure. The light-emitting device 1 includes a package holder 110, a light-emitting element 2, a reflective layer 130 and a wavelength conversion layer 140.

The package holder 110 includes a base 111 and a side plate 112, and the base 111 and the side plate 112 may be formed integrally or separately. The base 111 has a first surface 111a and a second surface 111b opposite to each other, and the side plate 112 is arranged on the first surface 111a along the circumference of the base 111. The base 111 and the side plate 112 form a cavity 120 for accommodating the light-emitting element 2, and the sidewall of the side plate 112 close to one side of the cavity 120 is the inner wall 112s of the side plate 112. The package holder 110 also includes a first electrode pad 113 and a second electrode pad 114. In some other embodiments, the package holder may also be a planar substrate.

The light-emitting element 2 is mounted on the first surface 111a of the base 111 in the form of a flip chip. A first pad electrode 292 and a second pad electrode 291 of the light-emitting element 2 are electrically connected to the first electrode pad 113 and the second electrode pad 114, respectively. In flip-chip mounting, the substrate side opposite to the surface where the pad electrode 290 is formed is set upward as the main light extraction surface. In other embodiments, the light-emitting element 2 may also be disposed in the light-emitting device 1 in a vertical chip structure.

The reflective layer 130 is disposed on the side plate 112, so it is possible to reduce the absorption of light emitted by the light-emitting element 2 by the package holder 110, and improve the light-emitting efficiency of the semiconductor light-emitting device. Specifically, the reflective layer 130 may be a metal reflective layer (such as Ag, Al and other materials with high reflectivity), or an insulating reflective layer (such as DBR), or a reflective adhesive material (such as white adhesive), and the thickness thereof is preferably less than 5 μm.

The wavelength conversion layer 140 covers the surface of the light-emitting element 2, and seals the light-emitting element 2 on the package holder 110. The wavelength conversion layer 140 is composed of an adhesive layer 141 and a wavelength conversion material 142. The adhesive layer 141 disperses the wavelength conversion material 142 around the light-emitting element 2, and the wavelength conversion material 142 and the light-emitting element 2 cooperate with each other to emit white light. The material of the adhesive layer 141 includes at least one of silica gel and epoxy resin. The wavelength conversion material 142 may be made of one or more combinations of phosphor powder, quantum dots, and organic fluorescent/phosphorescent materials. In an embodiment, the wavelength conversion material 142 may be phosphor powder, including red powder ((SrxCa1−x)AlSiN3) and yellow powder or green powder (YAG, LuAG, GaYAG, etc.), so that the wavelength conversion material 142 is able to accept excitation of the light-emitting elements 2 of different wavelengths and finally emit white light.

In some specific application scenarios (such as illumination for plant), the wavelength conversion material 142 may include a first wavelength conversion material 142a and a second wavelength conversion material 142b. Light of the first wavelength emitted by the light-emitting element 2 is converted into light of a second wavelength by the first wavelength conversion material 142a, and converted into light of a third wavelength by the second wavelength conversion material 142b, so that the light emitted by the light-emitting device 1 has a wider color gamut and is closer to the spectrum of sunlight. In a preferred implementation, the blue light of a wavelength of 430 nm to 470 nm emitted by the light-emitting element 2 is converted into yellow light with a wavelength of 560 nm to 600 nm by the first wavelength conversion material 142a, and the blue light emitted by the light-emitting element 2 is converted into red light with a wavelength of 620 nm to 700 nm by the second wavelength conversion material 142b. In this way, the white light emitted by the light-emitting device 1 has a wider color gamut and is closer to the color spectrum of sunlight.

Hereinafter, the light-emitting element 2 disposed in the light-emitting device 1 will be described in detail.

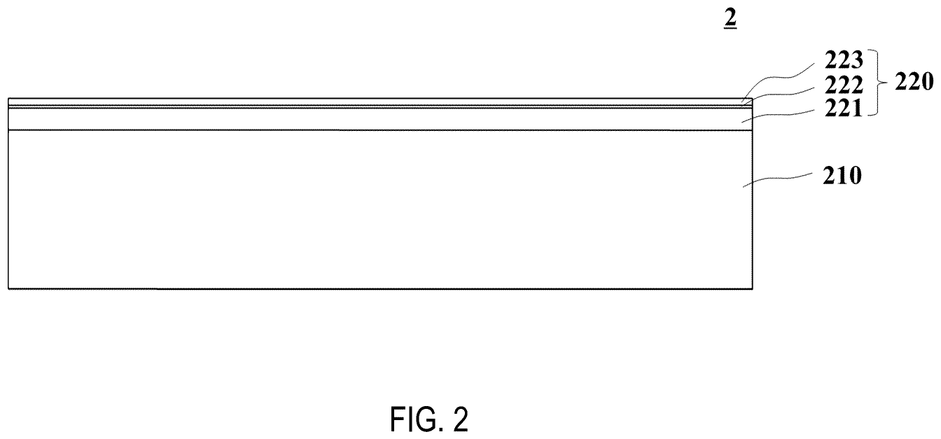

FIG. 2 to FIG. 25 are a manufacturing method and a structure of the light-emitting element 2 disclosed in an embodiment of the present disclosure.

As shown in FIG. 2, the manufacturing method of the light-emitting element 2 includes the steps of forming a semiconductor stack layer 220, which includes providing a substrate 210; and forming the semiconductor stack layer 220 on the substrate 210, wherein the semiconductor stack layer 220 includes a first semiconductor layer 221, a second semiconductor layer 223, and an active layer 222 located between the first semiconductor layer 221 and the second semiconductor layer 223.

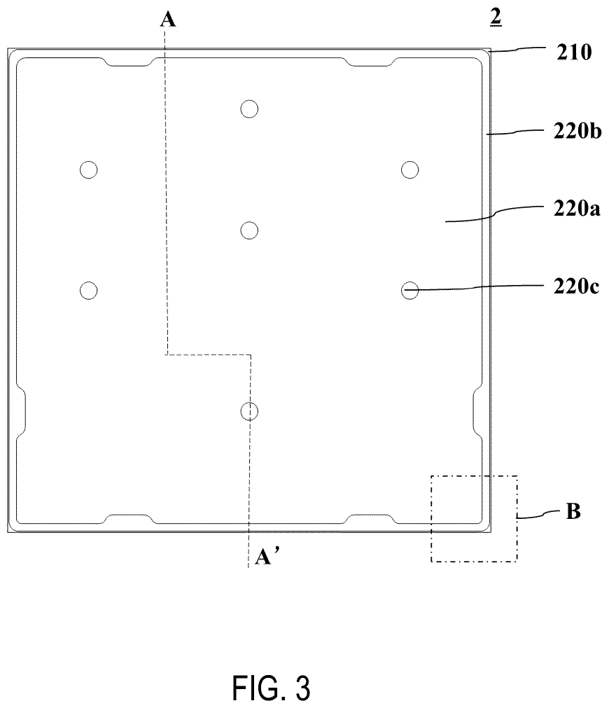

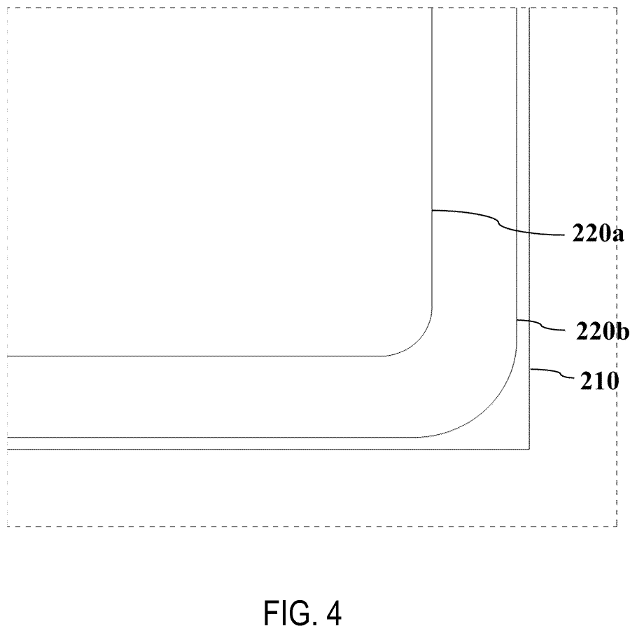

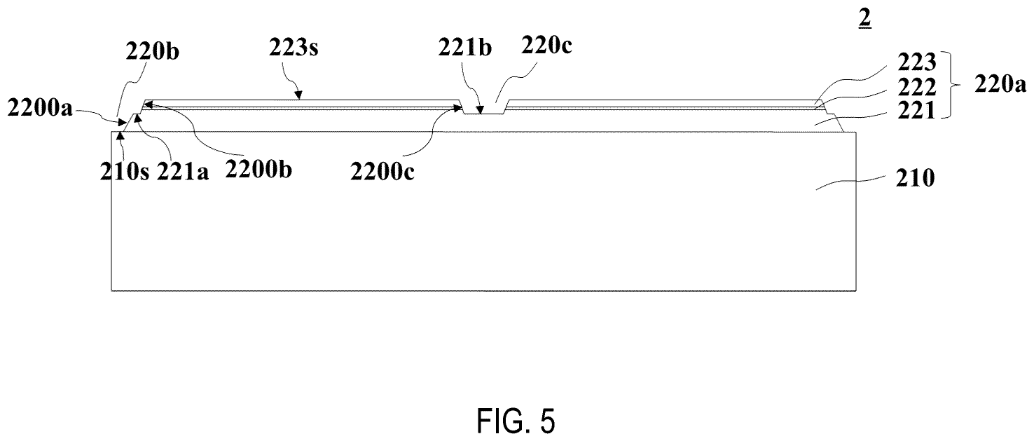

In an embodiment of the present disclosure, the substrate 210 may be formed by using a carrier wafer suitable for growing semiconductor materials. In addition, the substrate 210 may be formed of a material having excellent thermal conductivity or may be a conductive substrate or an insulating substrate. In addition, the substrate 210 may be formed of a light-transmitting material, and may have a mechanical strength that does not cause bending of the entire semiconductor structure 220a (see FIG. 3) and enables efficient division of separate chips through a scribing and breaking process. For example, the substrate 210 may adopt a sapphire (Al₂O₃) substrate, a silicon carbide (SiC) substrate, a silicon (Si) substrate, a zinc oxide (ZnO) substrate, a gallium nitride (GaN) substrate, a gallium arsenide (GaAs) substrate or a gallium phosphide (GaP) substrate or the like; specifically, a sapphire (Al₂O₃) substrate is preferable. In this embodiment, the substrate 210 is sapphire with a series of protrusions on the surface, including protrusions without a fixed slope formed by dry etching, or protrusions with a certain slope formed by wet etching.

In an embodiment of the present disclosure, a semiconductor stack layer 220 with photoelectric properties is formed on the substrate 210 by using metalorganic chemical vapor deposition (MOCVD), molecular beam epitaxy (MBE), hydride vapor deposition (HYPE), physical vapor deposition (PVD) or ion plating method, such as a light-emitting stack layer, and the physical vapor deposition method includes sputtering or evaporation. The first semiconductor layer 221, the active layer 222, and the second semiconductor layer 223 may be formed of a compound semiconductor of group III gallium nitride series, for example, GaN, AlN, InGaN, AlGaN, InAlGaN, and at least one selected from the above. The first semiconductor layer 221 is a layer that supplies electrons, and may be formed by implanting n-type dopants (e.g., Si, Ge, Se, Te, C, etc.). The second semiconductor layer 223 is a hole-supplying layer and may be formed by implanting p-type dopants (for example, Mg, Zn, Be, Ca, Sr, Ba, etc.). The active layer 222 is a layer in which electrons provided by the first semiconductor layer 221 and holes provided by the second semiconductor layer 223 recombine to output light of a predetermined wavelength, and may be formed from a multi-layer semiconductor thin film with a single-layer or multi-layer quantum well structure with alternately stacked potential well layers and barrier layers. The active layer 222 is formed by selecting different material combinations or proportions according to the wavelength of the output light. For example, the emission wavelength of the light-emitting element in the embodiment of the present disclosure is between 430 nm and 470 nm. The active layer 222 may be formed to have a pair structure including a well layer and a barrier layer using Group III to Group V compound semiconductor materials (for example, at least one of InGaN/GaN, InGaN/InGaN, GaN/AlGaN, InAlGaN/GaN, GaAs(InGaAs)/AlGaAs, or GaP(InGaP)/AlGaP), but the present disclosure is not limited thereto. The well layer may be formed of a material having an energy bandgap smaller than that of the barrier layer.

As shown in the top view of FIG. 3, the partially enlarged schematic diagram (corresponding to region B in FIG. 3) of FIG. 4 and the cross-sectional view of FIG. 5 along line A-A′ of FIG. 3, after the semiconductor stack layer 220 is formed on the substrate 210, the manufacturing method of the light-emitting element 2 includes a semiconductor structure forming step. The semiconductor stack layer 220 is patterned by photolithography and etching; a portion of the second semiconductor layer 223 and a portion of the active layer 222 are removed; one or more semiconductor structures 220a are formed; a surrounding portion 220b is formed to surround one or more semiconductor structures 220a to expose a first surface 221a of the first semiconductor layer 221; and one or more holes 220c are provided to expose a second surface 221b of the first semiconductor layer 221. The hole 220c may be regularly provided on the semiconductor stack layer 220. However, it should be understood that the present disclosure is not limited thereto, and the arrangement and number of the hole 220c may be changed in various ways. The exposed area of the first semiconductor layer 221 is not limited to a shape corresponding to the shape of the hole 220c. For example, the exposed region of the first semiconductor layer 221 may have a shape of a line or a combination of a hole and a line.

In an embodiment of the present disclosure, the plurality of semiconductor structures 220a may be separated from each other to expose a surface 210s of the substrate 210 or connected to each other through the first semiconductor layer 221. Each of the one or more semiconductor structures 220a includes a first outer sidewall 2200a, a second outer sidewall 2200b, and one or more inner sidewalls 2200c. The first outer sidewall 2200a is the sidewall of the first semiconductor layer 221, and the second outer sidewall 2200b is the sidewall of the active layer 222 and/or the second semiconductor layer 223. One end of the second outer sidewall 2200b is connected to a surface 223s of the second semiconductor layer 223, and the other end of the second outer sidewall 2200b is connected to the first surface 221a of the first semiconductor layer 221. One end of the inner sidewall 2200c is connected to the surface 223s of the second semiconductor layer 223, and the other end of the inner sidewall 2200c is connected to the second surface 221b of the first semiconductor layer 221. As shown in FIG. 5, an obtuse angle or a right angle is between the inner sidewall 2200c of the semiconductor structure 220a and the second surface 221b of the first semiconductor layer 221, an obtuse angle or a right angle is between the first outer sidewall 2200a of the semiconductor structure 220a and the surface 210s of the substrate 210, and an obtuse angle or a right angle is between the second outer sidewall 2200b of the semiconductor structure 220a and the first surface 221a of the first semiconductor layer 221.

In an embodiment of the present disclosure, the surrounding portion 220b has a rectangular shape or polygonal-ring shape viewed from the top view of the light-emitting element 2 shown in FIG. 3.

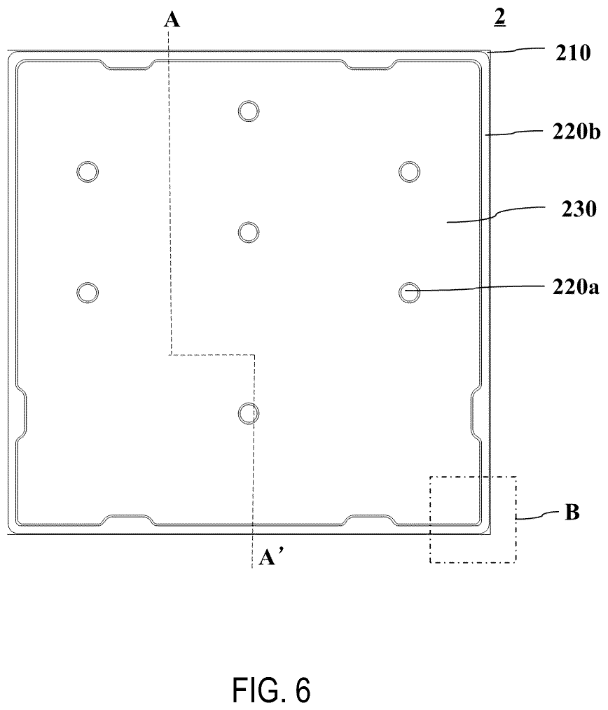

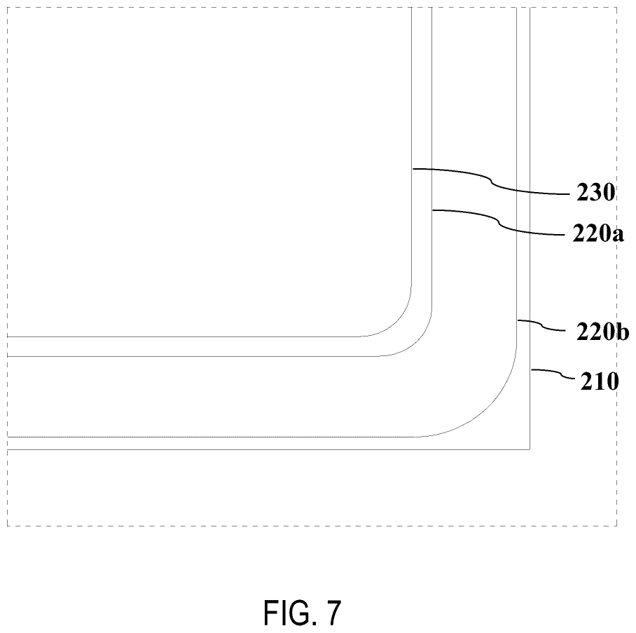

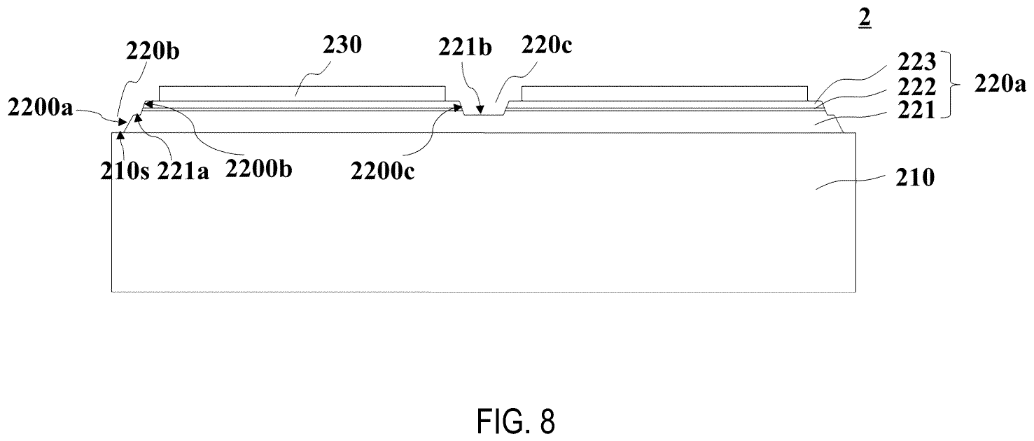

Following the step of forming a platform, as shown in the top view of FIG. 6, the partially enlarged schematic diagram of FIG. 7, and the cross-sectional view of FIG. 8 along the line A-A′ of FIG. 6, the manufacturing method of the light-emitting element 2 includes a step of forming a transparent conductive layer. A transparent conductive layer 230 is formed on the semiconductor structure 220a by means of physical vapor deposition or chemical vapor deposition, and is in contact with the second semiconductor layer 223. The material of the transparent conductive layer 230 may be ITO, InO, SnO, CTO, ATO, ZnO, GaP or a combination thereof. The transparent conductive layer 230 may be formed by evaporation or sputtering. The thickness of the transparent conductive layer 230 is selected from the range of 5 nm to 100 nm in this embodiment, and preferably selected from the range of 10 nm to 50 nm.

The transparent conductive layer 230 may be substantially in contact with almost the entire upper surface of the second semiconductor layer 223. In some embodiments, the transparent conductive layer 230 may be in contact with the entire upper surface of the second semiconductor layer 223. In this structure, current may be spread in the horizontal direction through the transparent conductive layer 230 when being supplied to the light-emitting element 2, and thus may be uniformly supplied to the entirety of the second semiconductor layer 223.

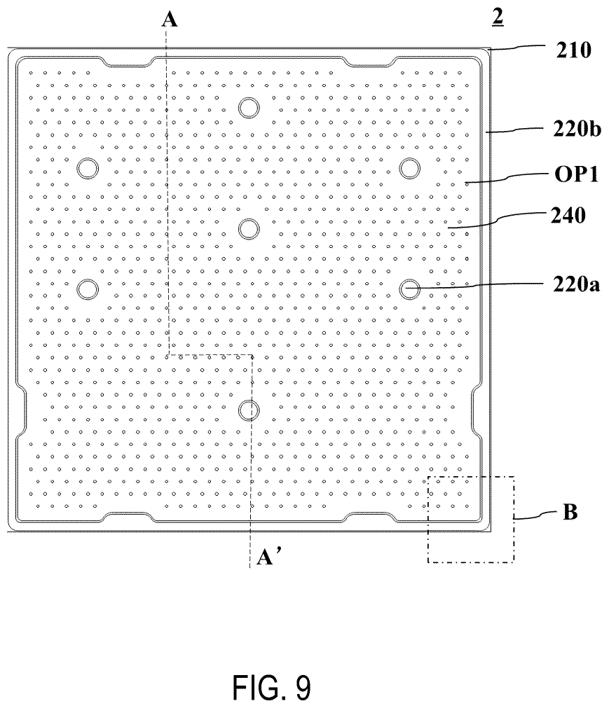

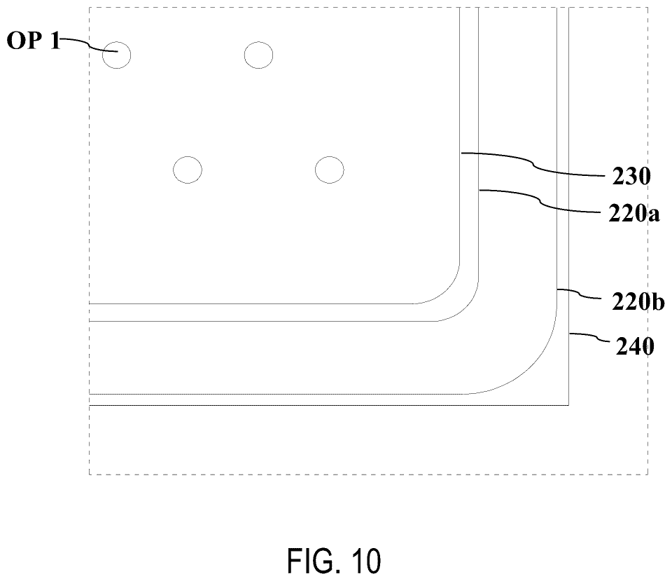

In an embodiment of the present disclosure, following the step of forming the transparent conductive layer, as shown in the top view of FIG. 9, the partially enlarged schematic diagram of FIG. 10, and the cross-sectional view of FIG. 11 along line A-A′ of FIG. 9, the manufacturing method of the light-emitting element 2 includes a step of forming the first insulating layer 240. The first insulating layer 240 is formed on the semiconductor structure 220a by physical vapor deposition or chemical vapor deposition, and then the first insulating layer 240 is patterned by photolithography and etching. The first insulating layer 240 may include one or more first openings OP1 to expose the surface of the transparent conductive layer 230. The first insulating layer 240 may cover a portion of the surface of the transparent conductive layer 230, the second outer sidewall 2200b of the semiconductor structure 220a, the second surface 221b of the first semiconductor layer 221, the first outer sidewall 2200a, the inner sidewall 2200c, and the first surface 221a of the first semiconductor layer. 221. When the hole 220c has an inclined sidewall, the first insulating layer 240 disposed on the sidewall of the hole 220c may be formed more stably.

The first insulating layer 240 may include at least one of SiO₂, SiN, SiOxNy, TiO₂, Si₃N₄, Al₂O₃, TiN, AlN, ZrO₂, TiAlN, TiSiN, HfO, TaO₂, and MgF₂. In exemplary embodiments, the first insulating layer 240 may have a multilayer film structure in which insulating films having different refractive indices are alternately stacked, and may be set as a distributed Bragg reflector (DBR). The multilayer film structure may be a structure in which first insulating film and second insulating film having a first refractive index and a second refractive index (as different refractive indices) are alternately stacked.

In another example embodiment, the first insulating layer 240 may be formed of a material having a lower refractive index than that of the second semiconductor layer 223. The first insulating layer 240 may constitute an omnidirectional reflector (ODR) together with the metal layer 250 disposed to contact an upper portion of the first insulating layer 240. In this way, the first insulating layer 240 may be used alone, or in combination with the metal layer 250, as a reflective structure that increases the reflectivity of light emitted from the active layer 222, thus significantly improving light extraction efficiency.

The thickness of the first insulating layer 240 may have a thickness in the range of 200 nm to 1500 nm, specifically, may have a thickness in the range of 300 nm to 1000 nm. When the thickness of the first insulating layer 240 is less than 300 nm, the forward voltage is high and the light output is low, which is not desirable. On the other hand, if the thickness of the first insulating layer 240 exceeds 400 nm, the light output is saturated. Therefore, preferably, the thickness of the first insulating layer 240 is not greater than 1000 nm, and especially may be less than 900 nm.

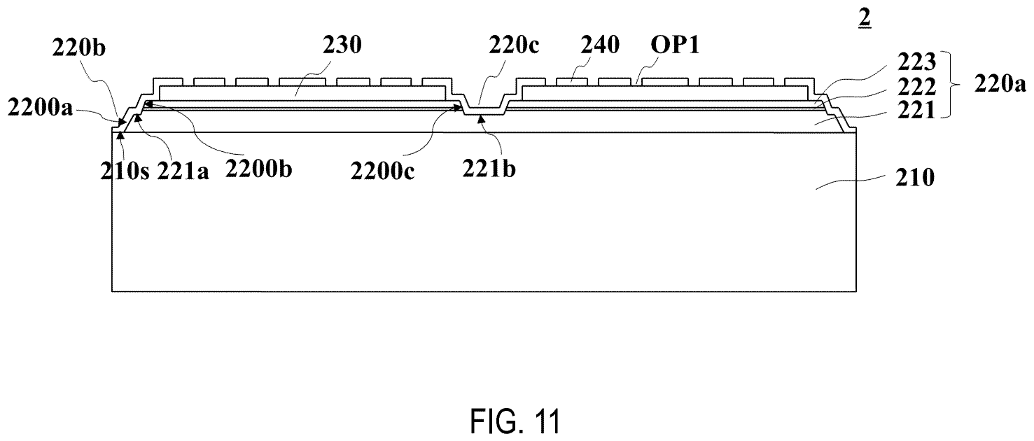

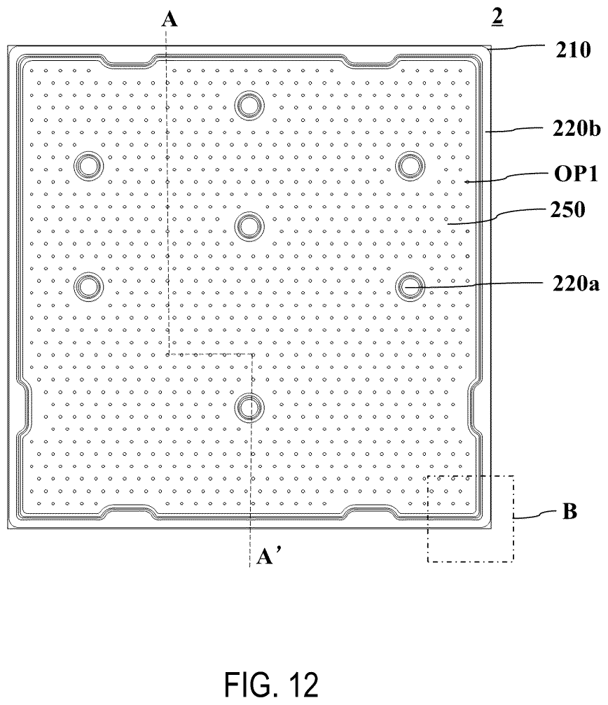

Following the step of forming the first insulating layer 240, as shown in the top view of FIG. 12, the partially enlarged schematic diagram of FIG. 13, and the cross-sectional view of FIG. 14 along the line A-A′ of FIG. 12, the manufacturing method of the light-emitting element 2 includes the step of forming the metal layer 250. The metal layer 250 is directly formed on the semiconductor structure 220a by means of physical vapor deposition or magnetron sputtering. The metal layer 250 is disposed on the first insulating layer 240 and in contact with the transparent conductive layer 230 through the first opening OP1 of the first insulating layer 240. The metal layer 250 includes a metal reflective layer 251 and/or a barrier layer 252, and the metal reflective layer 251 is located between the first insulating layer 240 and the barrier layer 252. The outer edge of the metal reflective layer 251 may be arranged on the inside or outside of the outer edge of the transparent conductive layer 230, or be arranged to be aligned with the outer edge of the transparent conductive layer 230, and the outer edge of the barrier layer 252 may be arranged on the inside or outside of the outer edge of the metal reflective layer 251, or arranged to be aligned with the outer edge of the metal reflective layer 251. In an embodiment of the present disclosure, the outer edge of the metal reflective layer 251 does not overlap with the outer edge of the transparent conductive layer 230, and the outer edge of the transparent conductive layer 230 is outside the outer edge of the metal reflective layer 251, so that the area of the transparent conductive layer 230 covering the semiconductor structure 220a may be larger than the area of the metal reflective layer 251, and the contact area between the semiconductor structure 220a and the transparent conductive layer 230 may be increased to reduce the voltage. The outer edge of the barrier layer 252 covers the outer edge of the metal reflective layer 251, which may prevent the components (such as silver or aluminum) of the metal reflective layer 251 from being diffused by heat or electricity, and the area of the barrier layer 252 larger than the metal reflective layer 251 still serves the reflection function.

In an embodiment of the present disclosure, in order to increase the adhesion between the metal reflective layer 251 and the first insulating layer 240, an adhesive layer is between the metal reflective layer 251 and the first insulating layer 240 (not shown).

In an embodiment of the present disclosure, the metal reflective layer 251 may be formed as a single-layer structure or a multi-layer structure of a conductive material having ohmic properties with the transparent conductive layer 230. The metal reflective layer 251 may be made of, for example, gold (Au), tungsten (W), platinum (Pt), iridium (Jr), silver (Ag), aluminum (Al), copper (Cu), nickel (Ni), titanium (Ti), chromium (Cr) and other materials and one or more of alloys thereof. Accordingly, current applied to the metal layer 250 may diffuse through the transparent electrode layer 130. The reflectivity of the metal reflective layer 251 is greater than 70%.

In an embodiment of the present disclosure, the barrier layer 252 wraps metal reflective layer 251 to avoid occurrence of surface oxidation on the metal reflective layer 251 and prevent reflectivity deterioration of the metal reflective layer 251, while blocking thermal diffusion or electromigration of active metal at the edge of the metal reflective layer 251. The material of the barrier layer 252 includes metal materials such as titanium (Ti), tungsten (W), aluminum (Al), indium (In), tin (Sn), nickel (Ni), platinum (Pt), chromium (Cr), Gold (Au), titanium tungsten (TiW) and other metals or alloys of the above materials. The barrier layer 252 may be a single layer or a stacked structure, such as titanium (Ti)/aluminum (Al), and/or titanium (Ti)/tungsten (W). In an embodiment of the present disclosure, the barrier layer 252 includes a stacked structure containing titanium (Ti)/aluminum (Al) on one side close to the metal reflective layer 251, and includes a structure containing chromium (Cr) or platinum (Pt) on one side away from the metal reflective layer 251.

The light radiated by the semiconductor structure 220a can reach the surface of the metal layer 250 through the first insulating layer 240 and be reflected back by the metal layer 250, so the first insulating layer 240 has a certain transparency to the light emitted by the active layer. More preferably, according to the principle of light reflection, the first insulating layer 240 has a refractive index lower than that of the material of the semiconductor structure 220a, which allows a portion of the light radiated by the active layer 222 to reach the surface thereof to transmit or refract light at a small angle to the first reflective layer 130, and incident rays exceeding the total reflection angle are totally reflected back. Therefore, the light reflection effect of the combination of the first insulating layer 240 and the metal layer 250 is higher than that of the metal layer 250.

In order to ensure light reflectivity, the vertical projection area of the metal layer 250 is between 50% and 100% of the horizontal area of the upper surface 223s of the second semiconductor layer 223. In an optional embodiment, the metal reflective layer 251 is located in the vertical projection plane of the second semiconductor layer 223. In an optional embodiment, the vertical projection area of the transparent conductive layer 230 is larger than the vertical projection area of the metal reflective layer 251, that is, the contact area between the semiconductor structure 220a and the transparent conductive layer 230 is increased as much as possible to reduce the voltage.

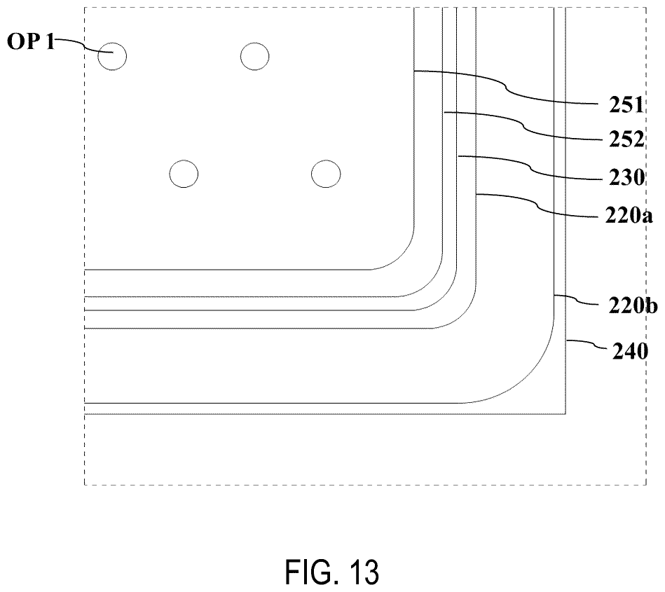

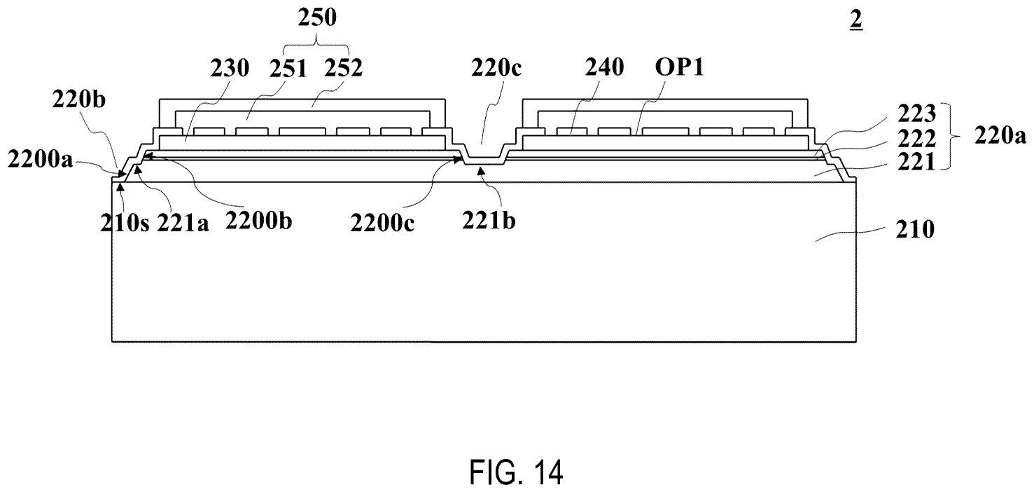

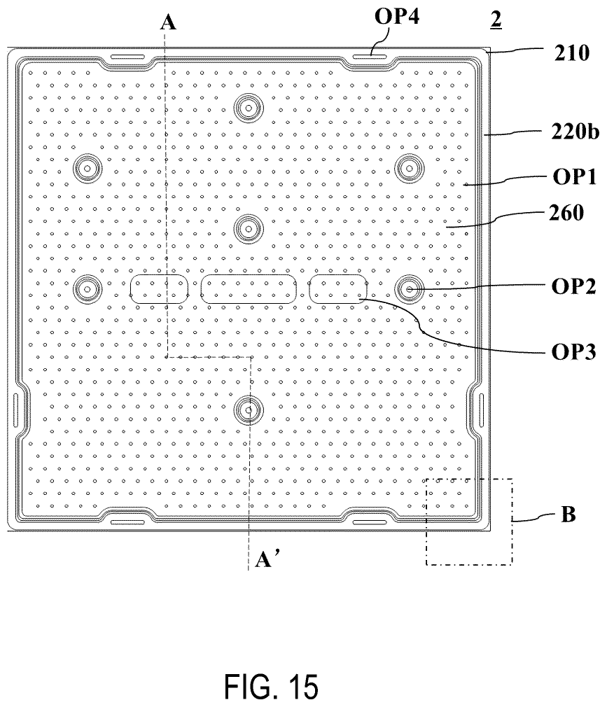

Following the step of forming the metal layer 250, as shown in the top view of FIG. 15, the partially enlarged schematic diagram of FIG. 16, and the cross-sectional view of FIG. 17 along the line A-A′ of FIG. 15, the manufacturing method of the light-emitting element 2 includes a step of forming the second insulating layer 260. The second insulating layer 260 is formed on the semiconductor structure 220a by means of physical vapor deposition or chemical vapor deposition, and then the second insulating layer 260 is patterned by photolithography and etching to form a second opening OP2 to expose the second surface 221b of the first semiconductor layer 221, a third opening OP3 to expose a portion of the surface of the metal layer 250, and a fourth opening OP4 to expose the first surface 221a of the first semiconductor layer 221. In the process of patterning the second insulating layer 260, in the step of forming the first insulating layer 240, the first insulating layer 240 covering the hole 220c is partially etched and removed to expose the second surface 221b of the first semiconductor layer 221, and the second opening OP2 is formed in the hole 220c to expose the first surface 221a of the first semiconductor layer 221.

The material of the second insulating layer 260 may be formed of substantially the same material as that of the first insulating layer 240, or may be different. The second insulating layer 260 may be a single layer or a stacked structure. When the second insulating layer 260 is a single-layer structure, the second insulating layer 260 may protect the sidewall of the semiconductor structure 220a to prevent the active layer 222 from being damaged in subsequent manufacturing processes. When the second insulating layer 260 is a stacked structure, the second insulating layer 260 may include two or more materials with different refractive indices stacked alternately to form a Bragg reflector (DBR) structure, which selectively reflects light of a specific wavelength.

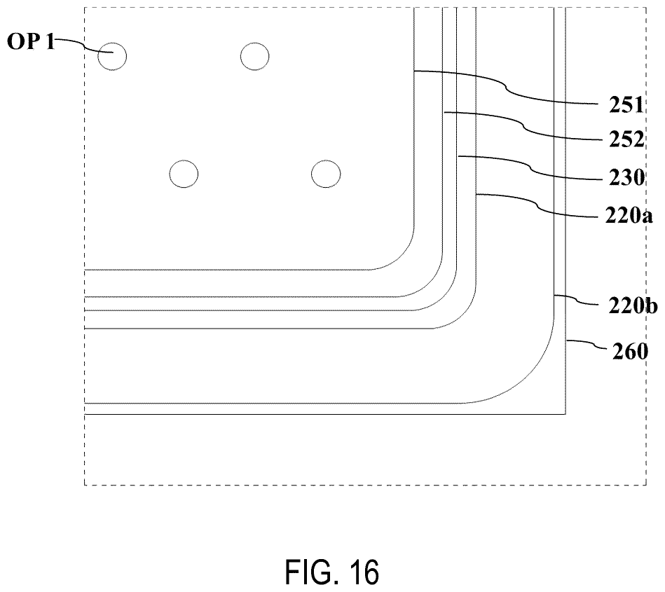

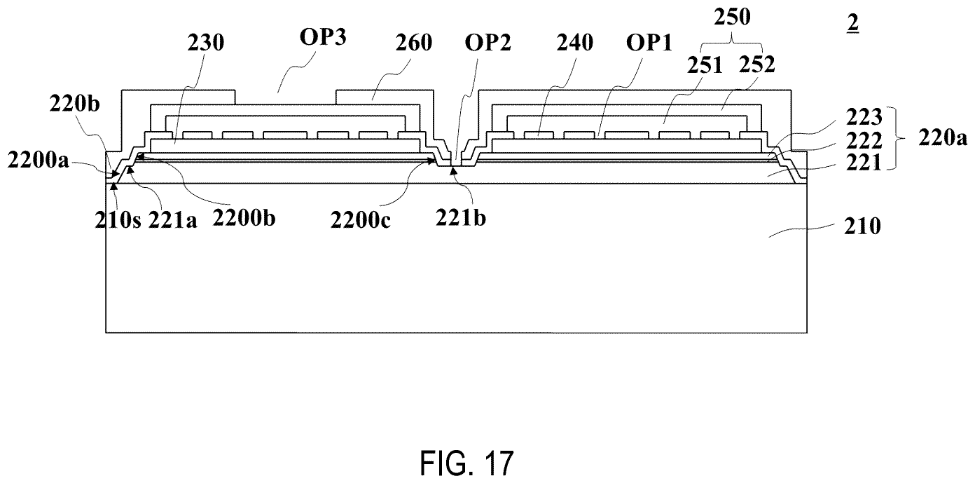

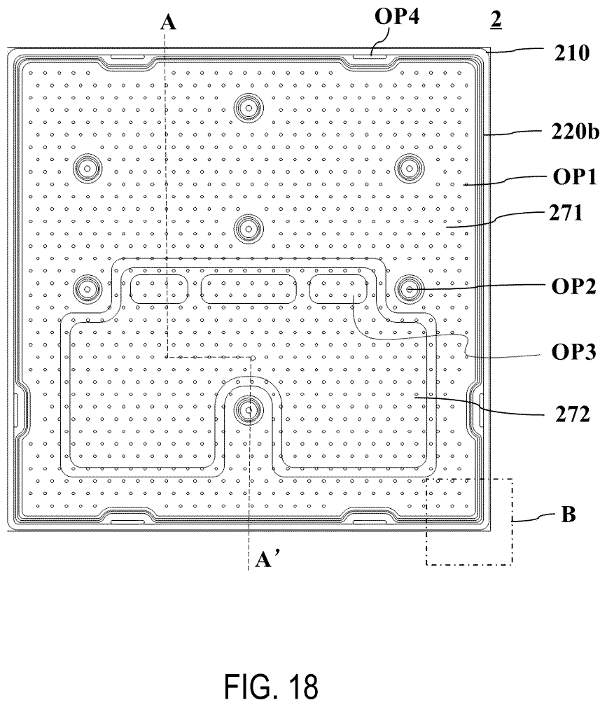

Following the step of forming the second insulating layer 260, as shown in the top view of FIG. 18, the partially enlarged schematic diagram of FIG. 19, and the cross-sectional view of FIG. 20 along the line A-A′ of FIG. 18, the manufacturing method of the light-emitting element 2 includes the step of forming a contact layer. The contact layer is formed on the semiconductor structure 220a by means of physical vapor deposition or magnetron sputtering. The contact layer is then patterned by photolithography and etching to form a first contact layer 271 and a second contact layer 272. The first contact layer 271 is filled in the hole 220c and covers the second opening OP2, so as to be in contact with the second surface 221b of the first semiconductor layer 221, and extends to cover a portion of the surface of the second insulating layer 260, and the first contact layer 271 is insulated from the second semiconductor layer 223 by the second insulating layer 260. The first contact layer 271 also covers the fourth opening OP4 and is in contact with the first surface 221a of the first semiconductor layer 221. The second contact layer 272 covers the third opening OP3 to be in contact with a portion of the metal layer 250, and extends to cover a portion of the surface of the second insulating layer 260. The second contact layer 272 is electrically connected to the second semiconductor layer 223 through the metal layer 250, and the second contact layer 272 does not overlap with the hole 220c in a projection direction perpendicular to the semiconductor stack layer.

In an embodiment of the present disclosure, the first contact layer 271 and the second contact layer 272 are separated from each other by a distance, so that the first contact layer 271 is not in contact with the second contact layer 272, and the first contact layer 271 is electrically isolated from the second contact layer 272 through a portion of the second insulating layer 260. As shown in FIG. 20, the first contact layer 271 is formed on a surrounding portion 220b formed on the semiconductor structure 220a, that is, formed on the second outer sidewall 2200b and a portion of the first outer sidewall 2200a on the semiconductor structure 220a, so that the first contact layer 271 surrounds a plurality of sidewalls of the second contact layer 272. In order to better spread the current, the area of the first contact layer 271 is larger than the area of the second contact layer 272.

In another embodiment (not shown), the first contact layer 271 may also be formed on the second outer sidewall 2200b on the semiconductor structure 220a, so that there is a sufficient distance between the first contact layer 271 and the edge of the substrate 210 of the light-emitting element 2 for the insulating layer to better cover the sidewall of the first contact layer 271, thus preventing short circuit of the light-emitting element 2 and improving the reliability of the light-emitting element 2.

The light-emitting element 2 mostly adopts the metal layer 250 (such as silver, aluminum) as the main reflector material to achieve better reflection of the light emitted by the light-emitting element 2. However, the metal layer 250 of the light-emitting element 2 does not completely cover the surface of the light-emitting element 2. The surface of the light-emitting element 2 in contact with the first contact layer 271 (that is, the second surface 221b of the first semiconductor layer 221 exposed by the hole 220c) and the edge of the light-emitting element 2 (that is, the peripheral area of the surrounding portion 220c of the semiconductor stack layer 220) are not covered by the metal layer 250. Therefore, the reflectivity of the material of the first contact layer 271 will also affect the brightness of the chip of the light-emitting element 2. In an embodiment of the present disclosure, in order to increase the light extraction efficiency of the light-emitting element 2, the first contact layer 271 includes metals with high reflectivity such as silver (Ag) and aluminum (Al). As shown in FIG. 20, the first contact layer 271 is formed in the hole 220c and in contact with the second surface 221b of the first semiconductor layer 221 and forms a good ohmic contact. However, it is difficult for the silver layer to directly form a good ohmic contact with the first semiconductor layer 221. Therefore, when the first contact layer 271 uses Ag as the reflective layer, it is preferable to set a first transition layer between the Ag reflective layer and the first semiconductor layer. The first transition layer may be chromium (Cr), Titanium (Ti) and other metals. Normally, the Ti layer needs to be annealed at high temperature to form a good ohmic contact with the first semiconductor layer 221. However, Ag easily diffuses during high temperature annealing, which might cause problems with the reflectivity and reliability of the light-emitting element 2. Therefore, in a preferred embodiment, the first transition layer may be Cr, and the first contact layer 271 may be selected from a Cr/Ag stack layer. Specifically, the thickness of Ag is preferably 50 nm to 300 nm. If the thickness of Ag is less than 50 nm, the effect of the reflectivity of the first contact layer 271 might not be good; if the thickness of Ag is greater than 300 nm, Ag is very likely to diffuse, and the reliability of the light-emitting element 2 is likely to be affected negatively.

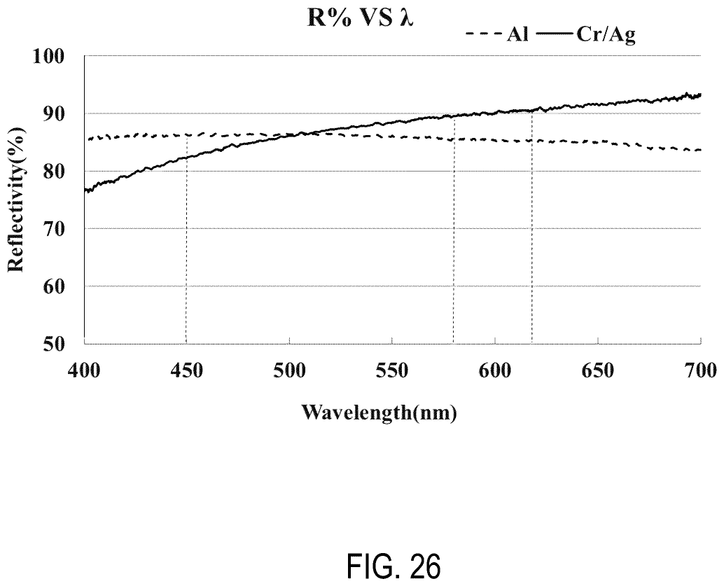

FIG. 26 shows the reflectivity at different wavelengths when the first contact layer is made of an Al layer as the bottom layer and the first contact layer is made of Cr/Ag as the bottom layer. As shown in FIG. 26, the reflectivity of Al to light with a wavelength of 450 nm is about 87.2%, and the reflectivity of Cr/Ag to light with a wavelength of 450 nm is about 82.1%, that is, the reflectivity of the Al layer to light with a wavelength of 450 nm is greater than the reflectivity of the Cr/Ag layer. From the perspective of the light extraction efficiency of the light-emitting element, the first contact layer 271 using the Al layer as the bottom layer may better achieve brightness improvement of the light-emitting element than the first contact layer 271 using Cr/Ag. However, in some specific application scenarios (such as illumination for plant), the wavelength conversion layer 140 in the light-emitting device 1 includes a wavelength conversion material for converting light into a yellow light band and a wavelength conversion material for converting light into a red light band, such as yellow phosphor and red phosphor, so that the light emitted by the light-emitting device 1 has a wider color gamut and is closer to the spectrum of sunlight. As shown in FIG. 26, the reflectivity of Al is about 87.2% when the wavelength is 450 nm, the reflectivity of the Al layer is about 85.7% when the wavelength is 580 nm, and the reflectivity of Al is about 85% when the wavelength is 620 nm. It may be seen from FIG. 26 that, with the increase of wavelength, the reflectivity of Al decreases gradually. In the light-emitting device 1, there might be some structures (for example, package holder, reflective layer, or wavelength conversion material) that will reflect a portion of the light emitted by the light-emitting element and a portion of the light in the yellow light band and/or the red light band converted by the wavelength conversion material into the light-emitting element. Specifically, the first contact layer 271 using an Al layer as the bottom layer has a reflectivity of the light in the yellow light band and the red light band lower than the reflectivity of the light in the blue light band. As a result, the reflection efficiency of light that is reflected out of the light-emitting element at the yellow light band and red light band converted by the wavelength conversion material might be reduced, and the white light conversion efficiency and light extraction efficiency of the light-emitting device are reduced.

In a preferred embodiment, the first contact layer 271 adopts Cr/Ag as the bottom layer. As shown in FIG. 26, the reflectivity of Cr/Ag to light with a wavelength of 450 nm is about 82.1%, the reflectivity of Cr/Ag to light with a wavelength of 580 nm is about 89.5%, and the reflectivity of Cr/Ag to light with a wavelength of 620 nm is about 90.8% %. It can be seen from FIG. 26 that the reflectivity of Cr/Ag to light with a wavelength of 450 nm is lower than that of Al, and the reflectivity of Cr/Ag to light with a wavelength of 580 nm and light with a wavelength of 620 nm is higher than that of Al. Specifically, the reflectivity of Cr/Ag to the light in the blue light band is about 5% lower than that of Al, while the reflectivity of Cr/Ag to the light in the yellow light band and red light band is about 5% higher than that of Al. In comprehensive consideration, the first contact layer 271 using Cr/Ag as the bottom layer may increase the reflectivity of light at the yellow light band and red light band converted by the wavelength conversion material and reflected to the surface of the light-emitting element, thereby increasing white light conversion efficiency and light extraction efficiency of the light-emitting device. It should be noted that the reflectivity shown in FIG. 26 refers to the reflectivity at an angle of 10 degrees when the metal layer is coated on the glass substrate and the light is incident from the glass side. The thickness of the Al layer is about 300 nm, the thickness of the Cr layer in the Cr/Ag stack layer is about 10 angstroms, and the thickness of Ag is 120 nm.

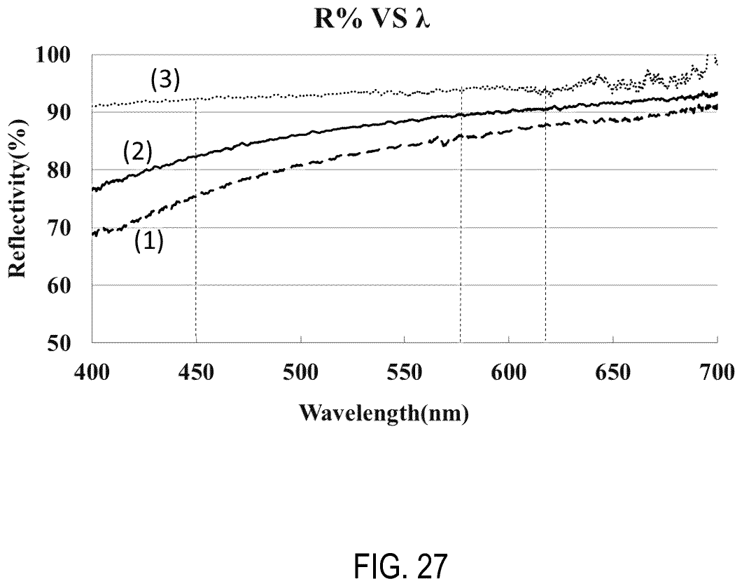

FIG. 27 shows the reflectivity curves under different thicknesses of Cr in the 400 nm to 700 nm band when the first contact layer 271 is Cr/Ag, where curve (1) is the reflectivity of Cr with a thickness of 20 angstroms, and curve (2) is the reflectivity of Cr with a thickness of 10 angstroms, and the curve (3) is the reflectivity of Cr with a thickness of 5 angstroms. It can be seen from FIG. 27 that the reflectivity of the curves (1), (2), and (3) increases gradually as the wavelength increases. Specifically, curve (1) has a reflectivity of 75.3% at 450 nm, a reflectivity of 85.8% at 580 nm, and a reflectivity of 87.5% at 620 nm; (2) the reflectivity is 82.1% at 450 nm, the reflectivity is 89.6% at 580 nm, the reflectivity is 90.9% at 620 nm; (3) the reflectivity is 92.4% at 450 nm, the reflectivity is 93.8% at 580 nm, and the reflectivity is 93.2% at 620 nm. It can be seen that the smaller the thickness of Cr is, the higher the reflectivity of the first contact layer 271 is to light at the 400 nm to 700 nm wavelength band. Therefore, in a preferred embodiment, the thickness of Cr is between 5 angstroms and 20 angstroms. If the thickness of Cr is greater than angstroms, it may affect the reflectivity of the first contact layer 271, affect the light extraction efficiency of the light-emitting element and the white light conversion efficiency of the light-emitting device. If the thickness of Cr is less than 5 angstroms, it might cause poor ohmic contact between the first contact layer 271 and the first semiconductor layer 221, thus affecting the photoelectric characteristics of the light-emitting element. In addition, if the thickness of Cr is too thin, it will also affect the adhesion between the first contact layer 271 and the insulating layer.

As shown in FIG. 18 and FIG. 20, the first contact layer 271 is not only formed in the hole 220c, but also formed on a portion of the surface of the second insulating layer 260. In an embodiment, when the first contact layer 271 contains Ag, a second transition layer is disposed between the Ag and the second insulating layer 260 to increase the adhesion between the Ag and the second insulating layer 260. The second transition layer may be metals such as chromium (Cr) and titanium (Ti). In a preferred embodiment, the second transition layer may be made of the same material as the first transition layer.

In an embodiment, the first contact layer 271 further includes other metals disposed on the Cr/Ag stack layer to prevent diffusion of Ag. The other metals may include metals such as chromium (Cr), titanium (Ti), aluminum (Al), platinum (Pt), nickel (Ni), tungsten (W) or any stacked layer of the above metal materials.

In an embodiment, the second contact layer may be made of the same material as that of the first contact layer 271 or may be made of a different material.

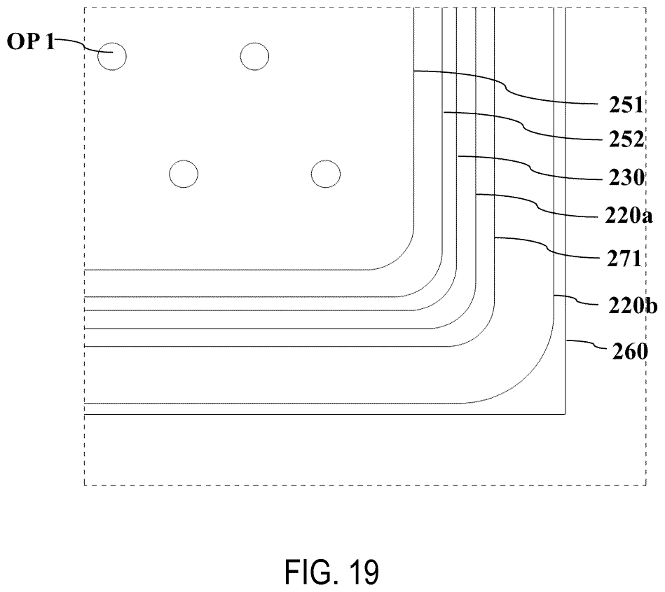

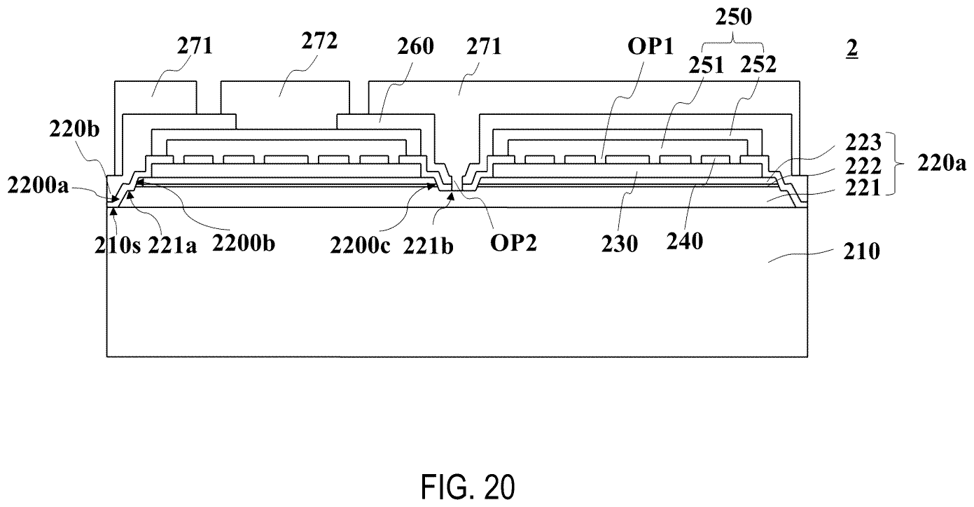

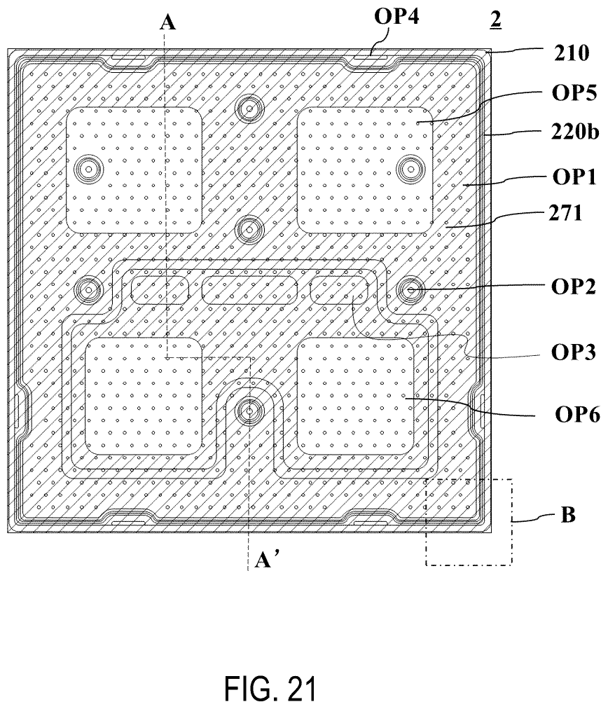

Following the step of forming the contact layer 270, as shown in the top view of FIG. 21, the partially enlarged schematic diagram of FIG. 22, and the cross-sectional view of FIG. 23 along line A-A′ of FIG. 21. The manufacturing method of the light-emitting element 2 includes a step of forming a third insulating layer 280. A third insulating layer 280 is formed on the semiconductor structure 220a by means of physical vapor deposition or chemical vapor deposition, and then the third insulating layer 280 is patterned by photolithography and etching to form a fifth opening OP5 and a sixth opening OP6 to expose the first contact layer 271 and the second contact layer 272, respectively.

In some embodiments, the third insulating layer 280 has a refractive index greater than 1.4. The third insulating layer 280 may include SiO₂, SiN, Al₂O₃, or the like. The third insulating layer 280 may be a multi-layer film structure formed by alternately stacking high-refractive-index dielectric films and low-refractive-index dielectric films, such as a Bragg reflection layer (DBR). Specifically, the material of the high-refractive-index dielectric film may be TiO₂, NB₂O₅, TA₂O₅, HfO₂, ZrO₂, etc.; the material of the low-refractive-index dielectric film may be SiO₂, MgF₂, Al₂O₅, SiON, etc. The thickness of the third insulating layer 280 is between 500 nm and 1500 nm. The total area of the plurality of fifth openings OP5 and the plurality of sixth openings OP6 in the third insulating layer 280 is preferably greater than 20% of the total area of the semiconductor stack layer 120.

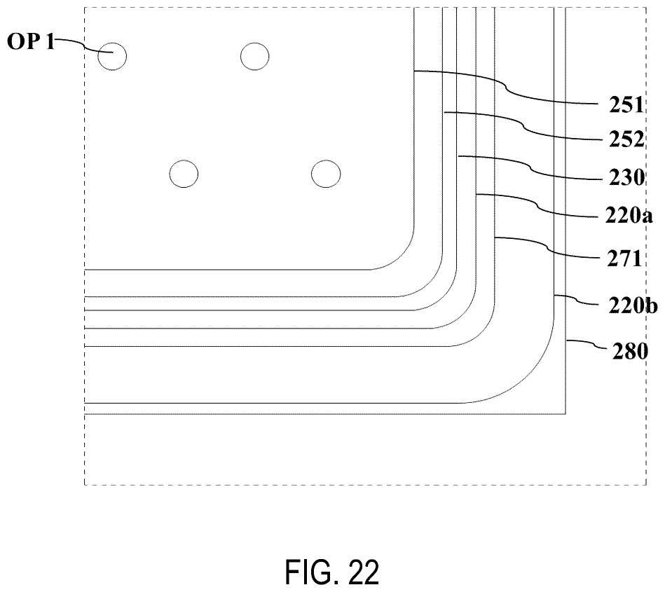

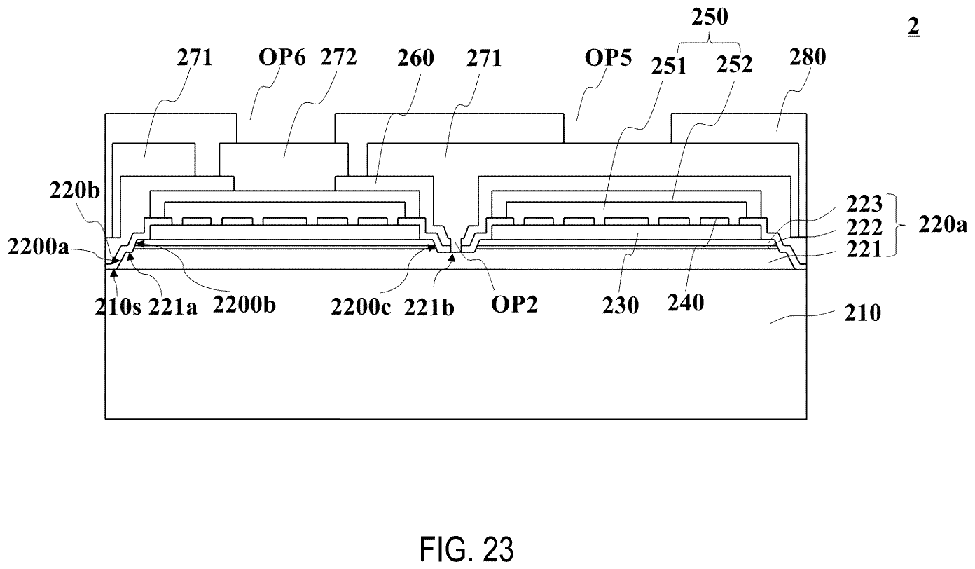

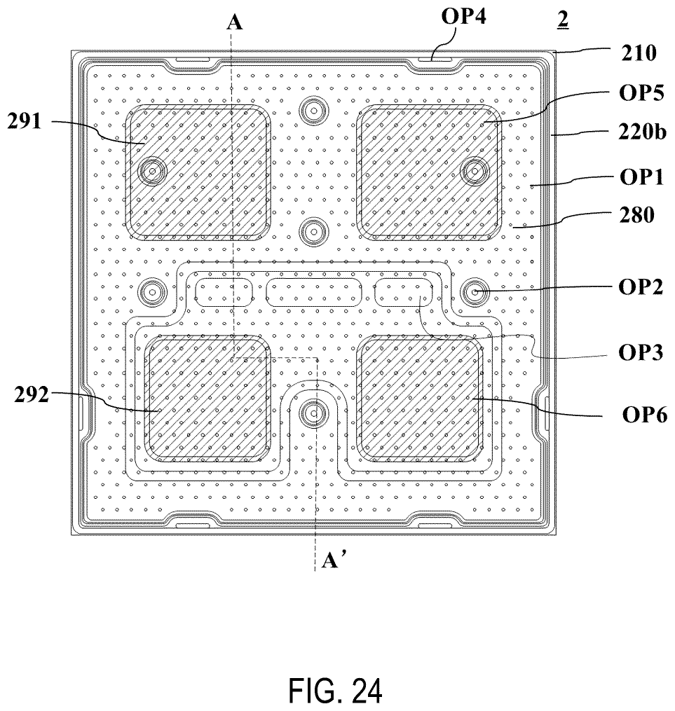

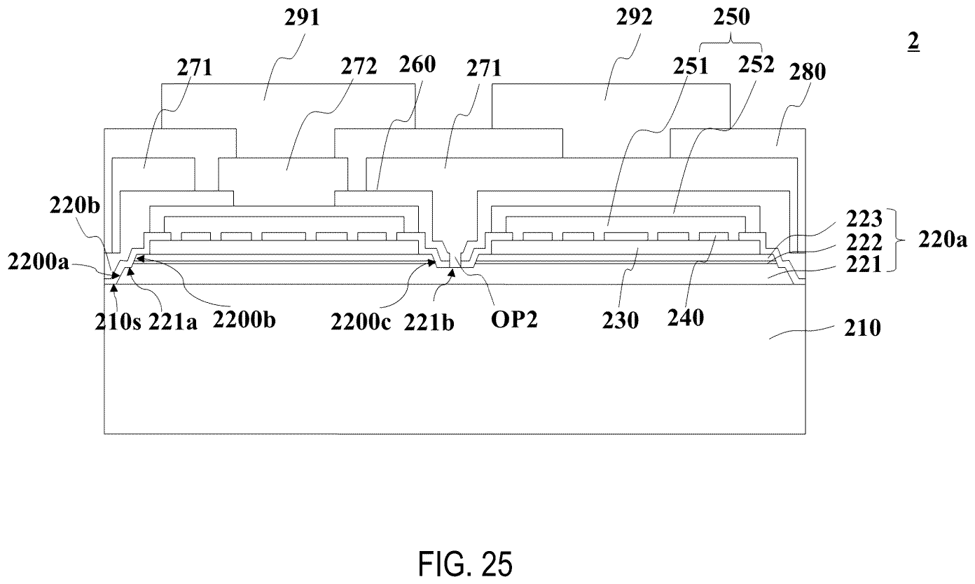

Following the third insulating layer forming step, the manufacturing method of the light-emitting element 2 includes a pad electrode forming step. As shown in the top view of FIG. 24 and the cross-sectional view of FIG. 25 along line A-A′ of FIG. 24, a first pad electrode 292 and a second pad electrode 291 are formed on one or more semiconductor structures 220a by means of electroplating, physical vapor deposition, or chemical vapor deposition. The first pad electrode 292 covers the fifth opening OP5 to be in contact with the first contact layer 271 and is electrically connected to the first semiconductor layer 221 through the first contact layer 271 and the hole 220c. The second pad electrode 291 covers the sixth opening OP6 to be in contact with the second contact layer 272, and is electrically connected to the second semiconductor layer 223 through the second contact layer 272 and the metal layer 250.

In an embodiment, the second pad electrode 291 does not overlap with the hole 220c in the projection direction perpendicular to the semiconductor stack layer, so that it is possible to increase the bonding between the light-emitting element 2 and the light-emitting device 1.

Generally, the materials of the pad electrodes (such as the first pad electrode 292 and the second pad electrode 291) include Ti, Al, Ni, Pt, Au, and the outermost layer is Au. In order to facilitate the packaging and use of the light-emitting element 2, in some embodiments, a solder layer may be added on the pad electrodes (such as the first pad electrode 292 and the second pad electrode 291). The solder layer is a material containing Sn, such as a Sn—Ag—Cu alloy or a Sn—Sb alloy. The liquidus melting point of the solder layer is 200° C. to 250° C. The thickness of the solder layer may be 601 μm to 100 μm, so as to ensure that the light-emitting element 2 has enough solder for soldering at the packaging end. In some embodiments, the thickness of the solder layer may be 80±10 μm. The arrangement of the solder layer may facilitate subsequent die-bonding packaging of the light-emitting element 2 and reduce the risk of electric leakage.

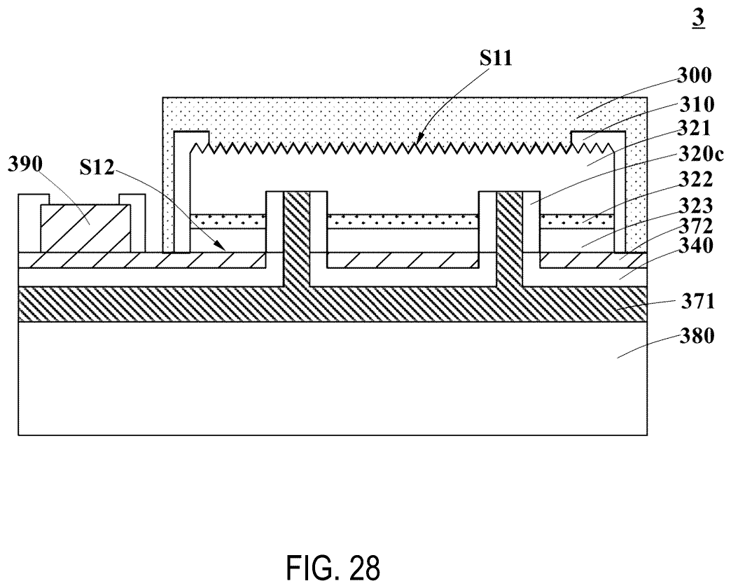

In another embodiment, as shown in FIG. 28, a light-emitting element 3 includes a wavelength conversion layer 300, a first insulating layer 310, a semiconductor stack layer (not labelled), a second insulating layer 340, a first contact layer 371, a second contact layer 372, a metal substrate 380, and an electrode 390. The semiconductor stack layer includes a first semiconductor layer 321, a second semiconductor layer 323 and an active layer 322 located between the first semiconductor layer 321 and the second semiconductor layer 323. The semiconductor stack layer has an upper surface S11 and a lower surface S12 opposite to the upper surface S11, the upper surface S11 is the surface of the first semiconductor layer 321, and the lower surface S12 is the surface of the second semiconductor layer 323. The semiconductor stack layer has a hole 320c penetrating through the second semiconductor layer 323 and the active layer 322 as well as extending to a portion of the surface of the first semiconductor layer 321. The first insulating layer 310 covers the sidewall and a portion of the upper surface S11 of the semiconductor stack layer. The second contact layer 372 is located on the lower surface S12 of the semiconductor stack layer, that is, on the second semiconductor layer 323. The second contact layer 372 includes a metal reflective layer, such as Al or Ag, preferably with a reflectivity above 90%. The second insulating layer 340 covers the first contact layer 371, and has one or more openings which have an overlapping area with the hole 320c in the projection direction perpendicular to the semiconductor stack layer. The area of the opening is smaller than the hole 320c, that is, the second insulating layer 340 covers the sidewall of the hole 320c. The first contact layer 371 is in contact with the first semiconductor layer 321 through the hole 320c of the semiconductor stack layer. The metal substrate 380 is in electrical contact with the first semiconductor layer 321 through the first contact layer 371. The electrode 390 is in electrical contact with the second semiconductor layer 323 through the second contact layer 372. The wavelength conversion layer 300 is disposed above the semiconductor stack layer and may convert the light of the first wavelength emitted by the semiconductor stack layer into light of other wavelengths. In some specific application scenarios (such as illumination for plant), the wavelength conversion layer 300 in the light-emitting element 3 includes a wavelength conversion material for converting light into a yellow light band and a wavelength conversion material for converting light into a red light band, such as yellow phosphor and red phosphor powder, so the light in the light-emitting element 3 has a wider color gamut and is closer to the spectrum of sunlight. In a preferred embodiment, the light-emitting element 3 emits light of the first wavelength (430 nm-470 nm), and the wavelength conversion layer 300 converts light of the first wavelength into the second wavelength (560 nm-600 nm) and the third wavelength (620 nm-700 nm). The first contact layer 371 includes a Cr/Ag stack layer in contact with the first semiconductor layer 321. The reflectivity of Cr/Ag at the yellow light band and red light band is higher than that in the blue light band, so it is possible to greatly increase the reflectivity of light at the yellow light band and red light band converted by the wavelength conversion material and reflected to the surface of the light-emitting element, thereby increasing white light conversion efficiency and light extraction efficiency of the light-emitting device.

What is claimed is:

1. A light-emitting device, comprising:
a light-emitting element, which emits a light of a first wavelength;
a wavelength conversion layer, which covers the light-emitting element, wherein the wavelength conversion layer comprises a first wavelength conversion material and a second wavelength conversion material, the light of the first wavelength emitted by the light-emitting element is converted into a light of a second wavelength through the first wavelength conversion material, and the light of the first wavelength emitted by the light-emitting element is converted into a light of a third wavelength through the second wavelength conversion material;
wherein the light-emitting element comprises:
a semiconductor stack layer, which comprises a first semiconductor layer, a second semiconductor layer, and an active layer disposed between the first semiconductor layer and the second semiconductor layer;
a contact layer, wherein a portion thereof is in contact with the first semiconductor layer, and the contact layer comprises a plurality of metal stacks;
wherein a reflectivity of the contact layer to the third wavelength is greater than 85%, the reflectivity of the contact layer to the third wavelength is greater than a reflectivity of the contact layer to the first wavelength, a reflectivity of the contact layer to the second wavelength is greater than the reflectivity of the contact layer to the first wavelength, and the reflectivity of the contact layer to the third wavelength is greater than the reflectivity of the contact layer to the second wavelength.

2. The light-emitting device according to claim 1, wherein a band of the first wavelength is 430 nm to 470 nm, a band of the second wavelength is 560 nm to 600 nm, and a band of the third wavelength is 620 nm to 700 nm.

3. The light-emitting device according to claim 1, wherein a material of the contact layer in contact with the first semiconductor layer is a chromium layer.

4. The light-emitting device according to claim 3, wherein a thickness of the chromium layer is 5 angstroms to 20 angstroms.

5. The light-emitting device according to claim 3, wherein a silver layer is on the chromium layer, and a thickness of the silver layer is 50 nm to 300 nm.

6. The light-emitting device according to claim 1, wherein the light-emitting element further comprises a metal layer disposed on the semiconductor stack layer, and the metal layer comprises silver or aluminum.

7. The light-emitting device according to claim 1, wherein the light-emitting element further comprises a pad electrode, the pad electrode comprises a first pad electrode and a second pad electrode, the contact layer comprises a first contact layer and a second contact layer, and the first contact layer is in contact with the first semiconductor layer, the second contact layer is in electrical contact with the second semiconductor layer, the first pad electrode is in electrical contact with the first semiconductor layer through the first contact layer, the second pad electrode is in electrical contact with the second semiconductor layer through the second contact layer.

8. The light-emitting device according to claim 7, wherein an area of the first contact layer is greater than an area of the second contact layer.

9. The light-emitting device according to claim 7, wherein the semiconductor stack layer comprises a hole, the hole exposes a portion of a surface of the first semiconductor layer, the second contact layer and the hole do not overlap each other in a projection direction perpendicular to the semiconductor stack layer, and the second pad electrode and the hole do not overlap each other in the projection direction perpendicular to the semiconductor stack layer.

10. The light-emitting device according to claim 1, further comprising a package holder, wherein the package holder comprises a base and a side plate, the base and the side plate form a cavity, and the light-emitting element is disposed in the cavity.

11. The light-emitting device according to claim 10, further comprising a reflective layer, wherein the reflective layer is located on the side plate.
